(19) United States
(12) Patent Application Publication
(10) Pub. No.: US 2014/0209999 A1
(43) Pub. Date: Jul. 31, 2014

(54) SEMICONDUCTOR DEVICE

(71) Applicant: Kabushiki Kaisha Toshiba, Tokyo (JP)

(72) Inventors: Nobuyuki SATO, Hyogo (JP); Kentaro ICHINOSEKI, Hyogo (JP)

(21) Appl. No.: 13/928,009

(22) Filed: Jun. 26, 2013

(30) Foreign Application Priority Data
Jan. 28, 2013 (JP) 2013-013703

(51) Int. Cl. H01L 29/78; H01L 29/66

(52) U.S. Cl. CPC H01L 29/7813; H01L 29/66734
USPC 257/330; 438/270

(57) ABSTRACT

A semiconductor device includes a first conductivity-type drain layer, a first conductivity-type drift layer formed on the drain layer, a second conductivity-type base layer formed on the drift layer, a first conductivity-type source layer which is selectively formed on a surface of the base layer, a trench region formed through a surface of the source layer such that the trench region reaches the drift layer from the surface of the source layer, a gate electrode formed adjacent to the base layer and inside the trench region, and surrounded by a first insulation film, a field plate electrode formed in the trench region below the gate electrode and surrounded by a second insulation film having a higher dielectric constant than the first insulation film, a drain electrode which is electrically connected to the drain layer, and a source electrode electrically connected to the source layer.

### CROSS-REFERENCE TO RELATED APPLICATION

This application is based upon and claims the benefit of priority from Japanese Patent Application No. 2013-013703, filed Jan. 28, 2013, the entire contents of which are incorporated herein by reference.

### FIELD

Embodiments described herein relate generally to a semiconductor device.

### BACKGROUND

In a Metal Oxide Semiconductor Field Effect Transistor (MOSFET) having the upper/lower electrode structure, the dopant concentration in a drift layer and a film thickness of the drift layer are adjusted to values within predetermined ranges to maintain an element breakdown voltage of the transistor when it is in an off state. The dopant concentration and the film thickness of the drift layer are limited based on boundaries of physical properties of a semiconductor material which is used for forming the drift layer. Accordingly, a trade-off relationship is established between the element breakdown voltage and an ON resistance.

A MOSFET in which a field plate electrode which is electrically connected to a source electrode or agate electrode is provided below a trench-type gate electrode, is known. By providing the field plate electrode below the gate electrode, when a voltage is applied to a drain electrode, a depletion region is formed between trenches. Accordingly, the dopant concentration in a drift layer can be increased without an element breakdown voltage being lowered, and hence, an ON resistance can be lowered in the MOSFET provided with the field plate electrode.

However, when the dopant concentration in the drift layer is increased too much, there is a possibility that the formation of the depletion region between the trenches is impaired. Without the properly formed depletion region, it is more difficult to ensure a proper breakdown voltage of the MOSFET.

### DESCRIPTION OF THE DRAWINGS

FIG. 1 is cross-sectional view of apart of a semiconductor device according to a first embodiment.

FIG. 2A to FIG. 2C are cross-sectional views showing manufacturing processes of the semiconductor device according to the first embodiment.

FIG. 3 is a cross-sectional view of a part of a semiconductor device according to a comparison example.

FIG. 4 is a cross-sectional view of a part of a semiconductor device according to a second embodiment.

FIG. 5A to FIG. 5C are cross-sectional views showing manufacturing processes of the semiconductor device according to the second embodiment.

### DETAILED DESCRIPTION

In general, according to one embodiment, a semiconductor device includes a first conductivity-type drain layer, a first conductivity-type drift layer formed on the drain layer, a second conductivity-type base layer formed on the drift layer, a first conductivity-type source layer which is selectively formed on a surface of the base layer, a trench region formed through a surface of the source layer such that the trench region reaches the drift layer from the surface of the source layer, a gate electrode formed adjacent to the base layer and inside the trench region, and surrounded by a first insulation film, a field plate electrode formed in the trench region below the gate electrode and surrounded by a second insulation film having a higher dielectric constant than the first insulation film, a drain electrode which is electrically connected to the drain layer, and a source electrode electrically connected to the source layer.

Hereinafter, embodiments are explained with reference to the drawings. The drawings used in the explanation of the embodiments are schematic views for facilitating the explanation of the embodiments. Accordingly, shapes, dimensions, the size relationship and the like of the respective elements in the drawings are not always limited to those described in the drawings, and they can be suitably changed where advantageous effects can be obtained.

In the embodiments, a first conductive-type is explained as an n-type and a second conductive-type is explained as a p-type. However, these conductive types may be reversed.

In the embodiments, a semiconductor that is made of silicon (Si) is explained as an example. However, a compound semiconductor made of silicon carbide (SiC), gallium nitride (GaN) or the like are applicable to the present invention.

In the embodiments, an insulation film that is made of silicon oxide is shown as an example. However, other insulators such as silicon nitride, silicon oxynitride, and alumina (Al₂O₃) can be used.

Further, when the n-type conductive type is expressed as “n⁺” or “n”, it is assumed that the n-type dopant concentration is lowered in this order. Also when the p-type conductive type is expressed as “p⁺” or “p”, the p-type dopant concentration is lowered in this order in the same manner as the n-type conductive type.

### First Embodiment

### Structure of Semiconductor Device 1a

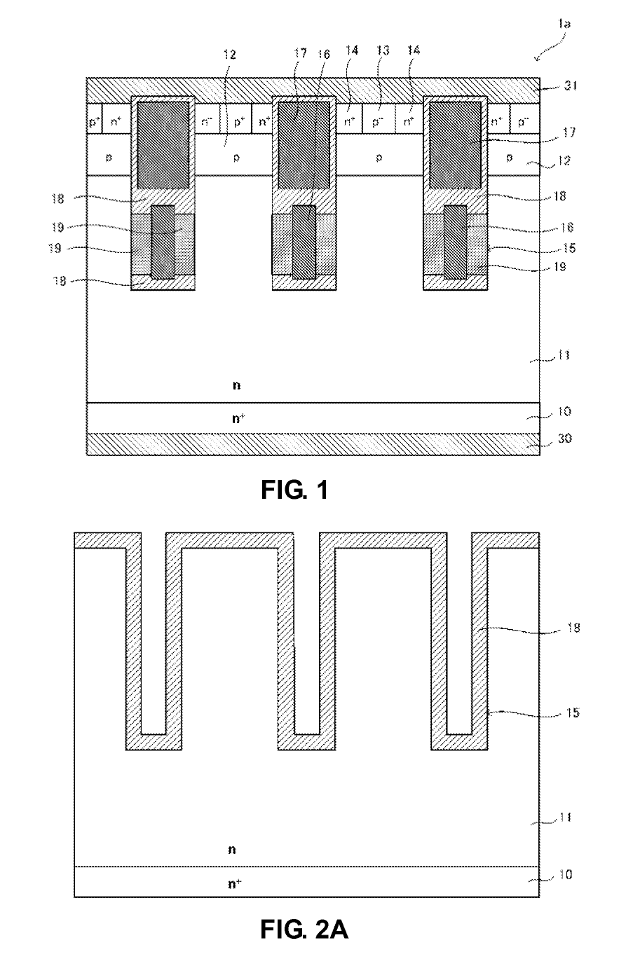

A semiconductor device 1a according to the first embodiment is explained with reference to FIG. 1. FIG. 1 is a cross-sectional view of a part of the semiconductor device 1a according to a first embodiment.

The semiconductor device 1a includes: an n⁺-type drain layer 10 (drain layer); an n-type drift layer 11 (drift layer); a p-type base layer 12 (base layer); p⁺-type contact layers 13; n⁺-type source layers 14 (source layers); trenches 15; field plate electrodes 16; gate electrodes 17; first insulation films 18; second insulation films 19; a drain electrode 30; and a source electrode 31.

The n⁺-type drain layer 10 is, for example, a silicon substrate. The n-type drift layer 11 having a lower n-type dopant concentration than the n⁺-type drain layer 10 is formed on the n⁺-type drain layer 10. The n-type drift layer 11 is, for example, an n-type epitaxial layer which is epitaxially formed and grown by a Chemical Vapor Deposition Method (CVD method).

The p-type base layer 12 is formed on the n-type drift layer 11. The p⁺-type contact layers 13 having a higher p-type dopant concentration than the p-type base layer 12 are formed on the p-type base layer 12. Then, the n⁺-type source layers 14 having a higher n-type dopant concentration than the n-type drift layer 11 are formed on the p-type base layer 12 in such a manner that the n⁺-type source layers 14 sandwich the p⁺-type contact layer 13 therebetween.

The plurality of trenches 15 are formed such that the trenches 15 reach the n-type drift layer 11 from surfaces of the p⁺-type contact layers 13 and the n⁺-type source layers 14. Upper side surfaces of the trenches 15 are brought into contact with the n⁺-type source layers 14. In other words, the trench 15 is formed between the n⁺-type source layers 14 arranged adjacent to each other.

The first insulation film 18 is formed on a bottom portion of the trench 15, and the field plate electrode 16 is formed on the first insulation film 18. The second insulation film 19 is formed on side surfaces of the field plate electrode 16, and the first insulation film 18 is also formed on a top portion of the field plate electrode 16. Further, the second insulation film 19 is in contact with side surfaces of the field plate electrode 16 and the trench 15. Thus, the field plate electrode 16 is surrounded by the first insulation film 18 and the second insulation film 19 in the trench 15.

The field plate electrode 16 is made of poly-silicon (poly-Si), for example. Further, materials for forming the first insulation film 18 and the second insulation film 19 are selected such that a dielectric constant of the second insulation film 19 is higher than a dielectric constant of the first insulation film 18. For example, the first insulation film 18 is made of silicon oxide (SiO₂; dielectric constant: 3.9), and the second insulation film 19 is made of silicon nitride (SiN; dielectric constant: 7.5). The field plate electrode 16 is electrically connected to the source electrode 31 and, therefore, has a source potential.

The gate electrode 17 is formed above the field plate electrode 16 and between the p-type base layers 12 arranged adjacent to it. The gate electrode 17 is surrounded by the first insulation film 18 in the trench 15. A thickness of the first insulation film 18 formed on the side surface of the gate electrode 17 (the thickness of the first insulation film 18 formed between the gate electrode 17 and the p-type base layer 12) is smaller than a thickness of the second insulation film 19 formed on the side surface of the field plate electrode 16 (the thickness of the second insulation film 19 formed between the field plate electrode 16 and the n-type drift layer 11). The gate electrode 17 is made of poly-silicon (poly-Si), for example.

The drain electrode 30 is formed such that the drain electrode 30 is electrically connected to the n⁺-type drain layer 10. The source electrode 31 is formed such that the source electrode 31 is electrically connected to the p⁺-type contact layers 13 and the n⁺-type source layers 14. The drain electrode 30 and the source electrode 31 are made of metal such as aluminum (Al) or copper (Cu), for example. The semiconductor device 1a according to the first embodiment has the above-mentioned configuration.

Although the MOSFET structure has been shown as an example of the semiconductor device 1a in this embodiment, the semiconductor device 1a is not limited to the MOSFET structure. The semiconductor device of the embodiment can be an Insulated Gate Bipolar Transistor (IGBT), for example. In case, a p-type collector region is formed between the n⁺-type drain layer 10 and the drain electrode 30.

(Manner of Operation of Semiconductor Device 1a)

The manner of operation of the semiconductor device 1a is explained.

For example, a positive voltage larger than a threshold voltage is applied to the gate electrode 17 in a state where a positive potential is applied to the drain electrode 30 with respect to the source electrode 31. In this case, an inversion layer is formed at a region of the p-type base layer 12 positioned adjacent to the side surface of the trench 15. Accordingly, the semiconductor device 1a is brought into an ON state resulting in a flow of an electron current.

This electron current flows to the drain electrode 30 from the source electrode 31 through the n⁺-type source layer 14, the n-type inversion layer (i.e., a channel of the semiconductor device 1a) formed in the p-type base layer 12, the n-type drift layer 11, and the n⁺-type drain layer 10. Thus, an electric current flows to the source electrode 31 from the drain electrode 30 in a state where the semiconductor device 1a is in an ON state.

On the other hand, if a voltage applied to the gate electrode 17 is zero or if a negative voltage is applied to the gate electrode 17, an inversion layer which forms an electron path disappears so that the electron current from the source electrode 31 is interrupted so that the semiconductor device 1a is brought into an OFF state (reverse bias applied state).

When the semiconductor device 1a is brought into the OFF state, due to a voltage applied between the source electrode 31 and the drain electrode 30, a depletion region forms toward the n-type drift layer 11 from an interface between the n-type drift layer 11 and the p-type base layer 12. Further, the field plate electrode 16 has a negative potential with respect to the drain electrode 30, and the n-type drift layer 11 has the same potential as the drain electrode 30. In addition, carriers in the n-type drift layer 11 are mainly electrons. Accordingly, electrons in the n-type drift layer 11 are discharged from an area in the vicinity of the field plate electrode 16 so that the area becomes depleted so that the depletion region spreads out toward the n-type drift layer 11 from interfaces between the n-type drift layer 11 and the second insulation films 19 (interfaces between the n-type drift layer 11 and side walls of the trench 15 in the vicinity of the field plate electrode 16). As a result, the depletion region is formed in the n-type drift layer 11 between the trenches 15 in three directions in total including the direction from a p-type base layer 12 side and the directions from side surfaces of two trenches 15.

The field plate electrode 16 is formed in the trench 15 and surrounded by the second insulation film 19 in the trench 15 so that the depletion region is formed in the n-type drift layer 11 in the three directions as described above so that the breakdown voltage of the semiconductor device 1a can be enhanced. This advantageous effect is referred to as a field plate effect.

As has been described above, the semiconductor device 1a is switched between the ON state and the OFF state by controlling a voltage of the gate electrode 17.

(Method of Manufacturing Semiconductor Device 1a)

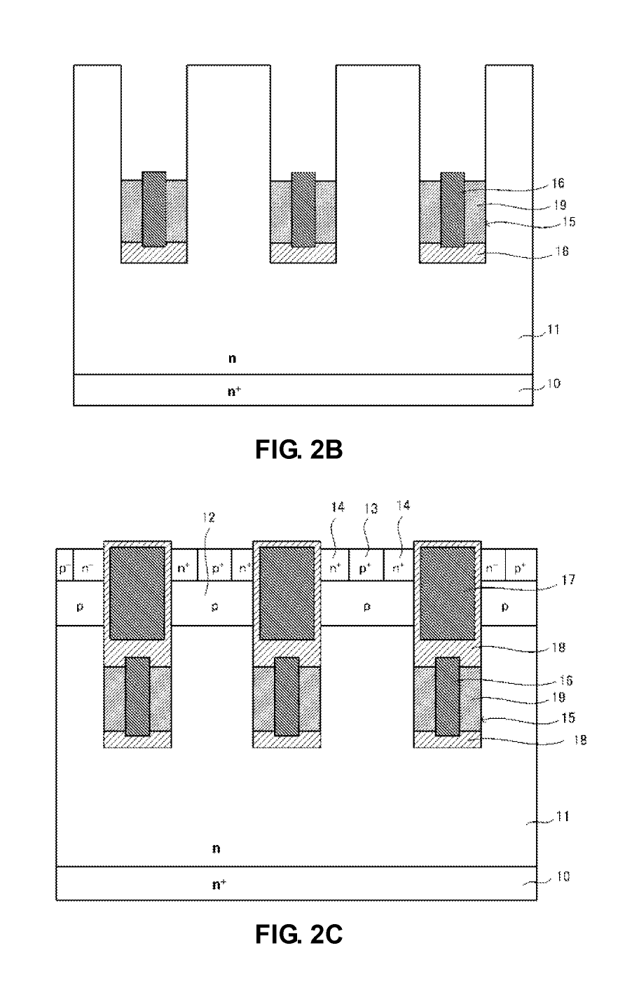

Next, the method of manufacturing the semiconductor device 1a according to the first embodiment is explained. FIG. 2A to FIG. 2C are cross-sectional views showing manufacturing processes of the semiconductor device 1a according to the first embodiment.

First, as described above, the n-type drift layer 11 is epitaxially formed and grown on a semiconductor substrate, which constitutes the n⁺-type drain layer 10. Then, the trenches 15 are formed by applying photolithography and a reactive ion etching (RIE) method to the n-type drift layer 11. Next, the inside (inner side walls) of the trenches 15 (except for portions where the field plate electrodes 16 are formed) and a surface of the n-type drift layer 11 are oxidized using thermal oxidation treatment, the CVD method, or the like thus forming the first insulation film 18 (silicon oxide) as shown in FIG. 2A.

Next, poly-silicon or amorphous silicon is deposited on the first insulation film 18 by the CVD method or the like. By implanting and diffusing phosphorus (P), for example, into the poly-silicon or the amorphous silicon, the field plate electrode 16 is formed in the trench 15. Then, the field plate electrode 16 is etched to a desired position. Next, the first insulation film 18 is etched to a desired position. To be more specific, the first insulation film 18 is etched such that the first insulation film 18 remains only on a bottom portion of the field plate electrode 16 and the side surfaces of the field plate electrode 16 are exposed. As a result, spaces are formed between the side surfaces of the field plate electrode 16 and the inner side walls of the trench 15.

Next, silicon nitride, alumina (Al₂O₃) or the like having a dielectric constant higher than a dielectric constant of the first insulation film 18 is deposited in the spaces formed between the side surfaces of the field plate electrode 16 and the inner side walls of the trench 15 by the CVD method or the like. Thus, the spaces are filled with the silicon nitride, the alumina (Al₂O₃) or the like, and the second insulation films 19 is formed as shown in FIG. 2B.

Heat treatment is applied to the above-mentioned structure in an oxidizing agent atmosphere such as hydrogen chloride (HCL) atmosphere thus forming the first insulation film 18 which constitutes a gate insulation film on the field plate electrode 16 and the second insulation films 19.

Poly-silicon or amorphous silicon is deposited on the newly formed first insulation film 18 by a CVD method or the like. Phosphorus (P) is implanted and diffused into this poly-silicon or amorphous silicon, for example, thus forming the gate electrode 17 in the trench 15.

Then, the p-type base layer 12 is formed by implanting a p-type dopant, such as boron (B), into the n-type drift layer between the trenches 15 to a desired depth by an ion implantation method. Next, the n⁺-type source layer 14 is formed by implanting an n-type dopant, such as phosphorus (P), into the n-type drift layer 11 by the ion implantation method. The n-type dopant is implanted to a desired depth such that the n-type dopant is positioned on a surface of the n-type drift layer 11.

Then, the first insulation film 18 is further formed on side surfaces and an upper portion of the n⁺-type source layer 14 and the side surfaces and an upper portion of the gate electrode 17 by the CVD method or the like. In this embodiment, the first insulation film 18 is formed such that a thickness of the first insulation film 18 formed on the side surfaces of the gate electrode 17 is smaller than a thickness of the second insulation film 19 formed on the side surfaces of the field plate electrode 16. The first insulation film 18 formed on the n⁺-type source layer 14 is suitably etched by the photolithography, the RIE method or the like.

Then, to establish an ohmic contact with the p-type base layer 12, a p-type dopant is implanted into a surface of the n-type drift layer 11 between the trenches 15 to a desired depth by the ion implantation method thus forming the p⁺-type contact layers 13. Thus, the p⁺-type contact layers 13 are formed such that the p⁺-type contact layer 13 is sandwiched between the n⁺-type source layers 14. Thereafter, heat treatment is performed so as to activate the implanted dopants (n-type and p-type) or the like thus providing the structure shown in FIG. 2C.

Next, the source electrode 31 is formed on the p⁺-type contact layers 13, the n⁺-type source layers 14, and the first insulation film 18, by a sputtering method or the like. In the same manner, the drain electrode 30 is formed on the n⁺-type drain layer 10 by the sputtering method or the like such that the drain electrode 30 is electrically connected to the n⁺-type drain layer 10. The semiconductor device 1a of the first embodiment shown in FIG. 1 is formed through the above-mentioned steps.

The above-mentioned manufacturing method is only one example. For example, as a film forming method, besides the CVD method, an atomic layer deposition (ALD) method where a growth control of an atomic layer can be performed in the form of a single body, the sputtering method, a physical vapor deposition (PVD) method, a coating method, a spraying method or the like can be used.

(Advantageous Effects of Semiconductor Device 1a)

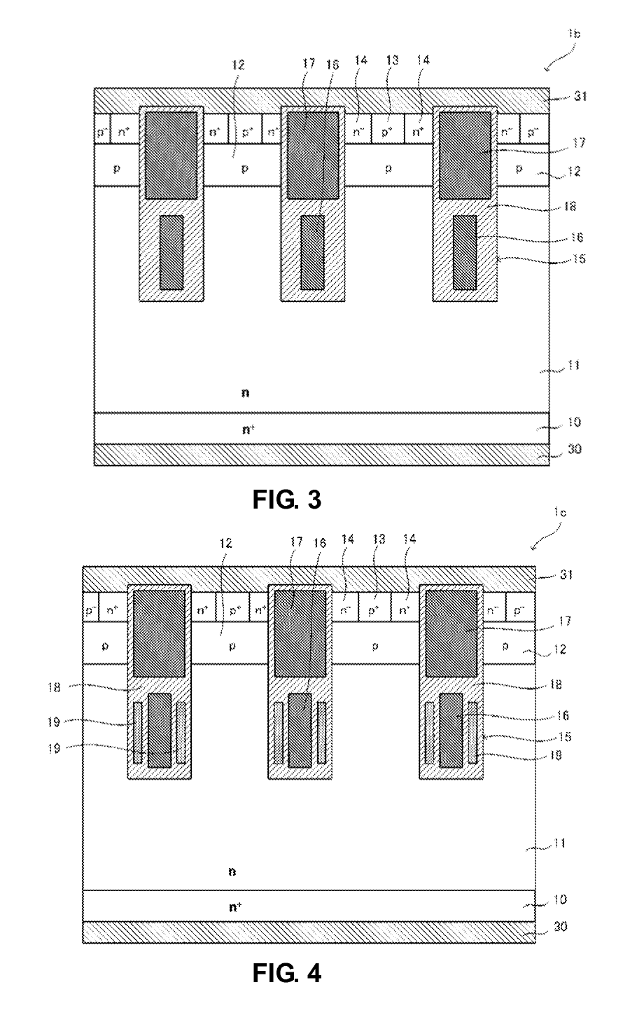

Advantageous effects acquired by the semiconductor device 1a of the first embodiment are explained with reference to a comparison example. FIG. 3 is a cross-sectional view of a part of a semiconductor device 1b according to the comparison example.

The semiconductor device 1b according to the comparison example differs from the semiconductor device 1a of the first embodiment in that a second insulation film 19 is not formed on side surfaces of a field plate electrode 16. Thus, the field plate electrode 16 and a gate electrode 17 are formed in the trench of the semiconductor device 1b surrounded by a first insulation film 18. The semiconductor device 1b is substantially the same as the semiconductor device 1a with respect to other configurations and the basic operations. Therefore, the explanation of other configurations and the basic operations of the semiconductor device 1b are omitted.

As described above, when the semiconductor device 1a is brought into an OFF state, the depletion region formed in the n-type drift layer 11 spreads downward from the interface between the n-type drift layer 11 and the p-type base layer 12. Also, the depletion region spreads inward from the interface between the n-type drift layer 11 and the second insulation film 19 (interface between the n-type drift layer 11 and the side walls of the trench 15 in the vicinity of the field plate electrode 16).

In the first embodiment, the second insulation film 19 having a dielectric constant higher than that of the first insulation film 18 is formed on the side surfaces of the field plate electrode 16. In general, a width of the depletion region in a drift layer is proportional to the magnitude of a dielectric constant of a insulation layer. Hence, the depletion region formed in the n-type drift layer 11 of the semiconductor device 1a can be wider compared to a depletion region formed in the n-type drift layer 11 of the semiconductor device 1b. Accordingly, a field plate effect can be enhanced so that a breakdown voltage of the semiconductor device 1a also can be enhanced.

Further, in the case of the semiconductor device 1a, the depletion region can be easily formed in the semiconductor device 1a, a thickness of the second insulation film 19 can be set larger than a thickness of the first insulation film 18 formed on side surfaces of the field plate electrode 16 of the semiconductor device 1b according to the comparison example. By setting the thickness of the second insulation film 19 larger than the thickness of the first insulation film 18 of the semiconductor device 1b, a dielectric breakdown strength of the semiconductor device 1a can be enhanced.

The reason that the second insulation films 19 of the semiconductor device 1a are formed in a spaced-apart manner from the bottom portion of the trench 15, that is, the reason that the second insulation films 19 of the semiconductor device 1a are formed on only the side surfaces of the field plate electrode 16 is as follows. Although the bottom portion of the trench 15 is depicted in a rectangular shape in FIG. 1, the bottom portion of the trench 15 is actually likely to have a curvature. If the bottom portion of the trench 15 has a curvature, electric field is likely to be concentrated in the bottom portion of the trench 15. Hence, when the second insulation film 19 having a high dielectric constant (such as the second insulation film 19) is formed on the bottom portion of the trench 15, a breakdown is likely to occur in the bottom portion of the trench 15. Accordingly, the second insulation film 19 is formed only on the side surfaces of the field plate electrode 16.

To further enhance the above-mentioned depletion region forming obtained by the formation of the second insulation film 19, a dielectric constant of the second insulation film 19 may be increased. For example, when silicon nitride is used for forming the second insulation film 19, a dielectric constant of the second insulation film 19 can be increased by increasing the concentration of nitride in the silicon nitride. As a manufacturing process for forming such a second insulation film 19, for example, following steps may be adopted. In this process, the first insulation film 18 is formed in the trench 15 by thermal oxidation or the like and, thereafter, the ion implantation of nitrogen ion is performed in an oblique direction such that the nitrogen ion is implanted into the first insulation film 18 formed on the side surfaces of the trench 15 thus forming the second insulation films 19 of high nitrogen concentration.

### Second Embodiment

A semiconductor device 1c according to a second embodiment is explained hereinafter with reference to FIG. 4. The explanation of the configurations of the semiconductor device 1c of the second embodiment that are substantially the same as the configuration of the semiconductor device 1a of the first embodiment, is omitted. Thus, only the configurations of the semiconductor device 1c of the second embodiment which differ from the configurations of the semiconductor device 1a are explained hereinafter.

(Structure of Semiconductor Device 1c)

FIG. 4 is a cross-sectional view of a part of a semiconductor device 1c according to the second embodiment. The semiconductor device 1c according to the second embodiment differs from the semiconductor device 1a according to the first embodiment in that a second insulation film 19 in the semiconductor device 1c is embedded in the first insulation film 18. Thus, the second insulation film 19 in this embodiment is formed in a floating state.

Specifically, the first insulation film 18 is formed between the second insulation films 19 and inner side walls of a trench 15 and between the second insulation films 19 and a field plate electrode 16. As described above, for example, the first insulation film 18 is made of silicon oxide and the second insulation film 19 is made of silicon nitride. Accordingly, the above-mentioned structure of the first and second insulation films is also referred to as the Oxide-Nitride-Oxide (ONO) film structure, which is the laminated structure made of silicon oxide and silicon nitride.

The manner of operation of the semiconductor device 1c is substantially the same as the manner of operation of the semiconductor device 1a and, hence, the explanation for the manner of operation of the semiconductor device 1c is omitted.

(Method of Manufacturing Semiconductor Device 1c)

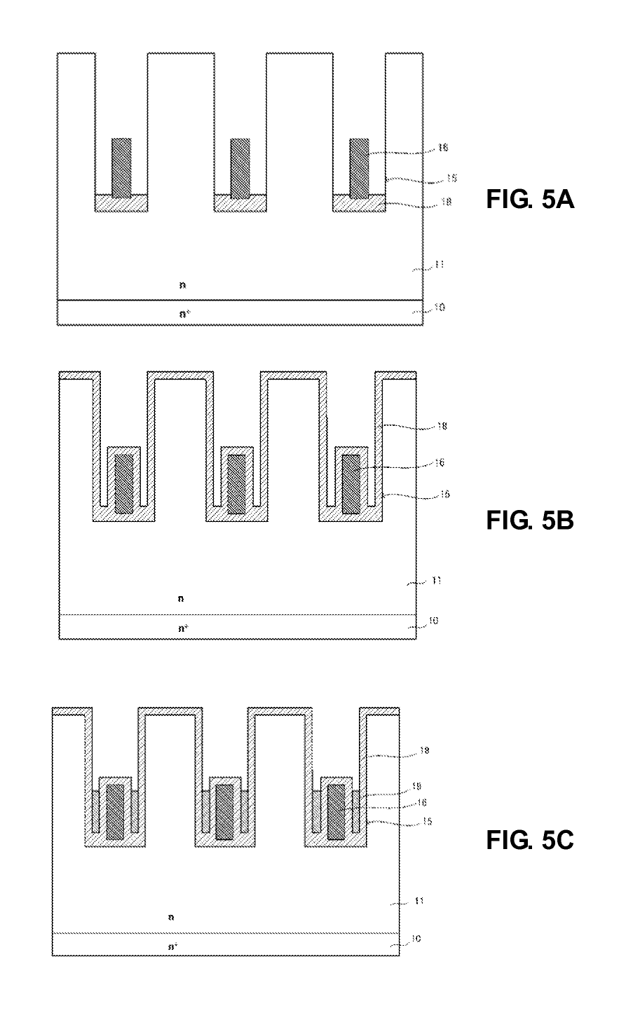

Next, the method of manufacturing the semiconductor device 1c of the second embodiment is explained. FIG. 5A to FIG. 5C are cross-sectional views showing manufacturing processes of the semiconductor device 1c according to the second embodiment.

First, as described above, an n-type drift layer 11 is epitaxially formed on a semiconductor substrate, which constitutes an n⁺-type drain layer 10. Then, the trenches 15 are formed in the n-type drift layer 11 by applying photolithography and an RIE method to the n-type drift layer 11. Next, the inside (inner side walls) of the trenches 15 (except for portions where the field plate electrodes 16 are formed) and a surface of the n-type drift layer 11 are oxidized using thermal oxidation treatment, a CVD method or the like thus forming the first insulation film 18 (silicon oxide). Next, poly-silicon or amorphous silicon is deposited on the first insulation film 18 by the CVD method or the like. By implanting and diffusing phosphorus (P), for example, into the poly-silicon or the amorphous silicon, the field plate electrode 16 is formed in the inside of the trench 15. Then, the field plate electrode 16 is etched to a desired position.

Further, as shown in FIG. 5A, the first insulation film 18 is etched to a desired position. Specifically, the first insulation film 18 is etched such that the first insulation film 18 remains only at a bottom portion of the trenches 15 and the first insulation film 18 formed between the side surfaces of the field plate electrode 16 and the inner walls of the trenches 15 are removed. As a result, spaces are formed between the side surfaces of the field plate electrode 16 and the inner side walls of the trench 15.

Next, the first insulation film 18 is formed on surfaces of the n-type drift layer 11, the trenches 15, and the field plate electrodes 16, using the thermal oxidation treatment, the CVD method or the like. Here, the first insulation film 18 is formed in such a manner that spaces in which the second insulation film 19 is to be filled later are ensured at positions adjacent to the side surfaces of the field plate electrode 16 (FIG. 5B).

Then, silicon nitride, alumina (Al₂O₃) or the like having a dielectric constant higher than a dielectric constant of the first insulation film 18 is deposited in the spaces formed between the first insulation film 18 formed on the side wall of the trench 15 and the first insulation film 18 formed on the side surface of the field plate electrode 16 by the CVD method or the like. Thus, the spaces are filled with the silicon nitride, the alumina (Al₂O₃) or the like, and the second insulation film 19 is formed as shown in FIG. 5C.

Manufacturing steps which follow the above-mentioned steps are substantially equal to the corresponding steps of the method of manufacturing the semiconductor device 1a and, hence, the explanation of these steps is omitted. The semiconductor device 1c of the second embodiment shown in FIG. 4 is formed through the above-mentioned steps.

The above-mentioned manufacturing method is only one example. For example, as a film forming method, besides the CVD method, an ALD method, a sputtering method, a physical vapor deposition (PVD) method, a coating method, a spraying method or the like can be used.

(Advantageous Effects of Semiconductor Device 1c)

Advantageous effects acquired by the semiconductor device 1c of the second embodiment are explained.

Also in the second embodiment, the second insulation film 19 having a dielectric constant higher than a dielectric constant of the first insulation film 18 is formed adjacent to the side of the field plate electrode 16. Thus, a depletion region formed in the n-type drift layer 11 of the semiconductor device 1c can spread more widely inward toward the n-type drift layer 11 from an interface between the n-type drift layer 11 and the second insulation film 19 when the transistor is turned off compared to the depletion region of the semiconductor device 1b. Accordingly, the field plate effect can be enhanced, and a breakdown voltage of the semiconductor device 1c can be enhanced.

Further, an advantageous effect acquired by providing the second insulation film 19 with the ONO film structure thus bringing the second insulation film 19 in a floating structure as in the case of the second embodiment is explained. When the second insulation film 19 having a high dielectric constant is provided in such a manner that the second insulation film 19 is in contact with the n-type drift layer 11 and the side surfaces of the field plate electrode 16 as in the semiconductor device 1a, there is a possibility that a breakdown voltage of the semiconductor device 1a is lowered. This is because an insulation film having a high dielectric constant has a narrow band gap and hence, when an electric field having high intensity is generated in an interface between the n-type drift layer 11 and the field plate electrode 16, there is a possibility that the implantation of carriers into the inside of the field plate electrode 16 occurs.

By surrounding the second insulation film 19 with the first insulation film 18 thus bringing the second insulation film 19 into a floating state as in the case of the semiconductor device 1c of the second embodiment, the above-mentioned implantation of carriers into the inside of the field plate electrode 16 can be suppressed. Hence, the semiconductor device 1c of the second embodiment can surely maintain the breakdown voltage of the semiconductor device 1c, which is enhanced due to the second insulation film 19 being formed in the trench 15.

In the above-mentioned embodiment, with respect to the second insulation film 19 of the semiconductor device 1c according to the second embodiment, the explanation has been made by reference to the case where only one second insulation film 19 is mounted on each side surface of the field plate electrode 16. However, the number of the second insulation films 19 is not particularly limited. Provided that the semiconductor device 1c has the structure where the second insulation film 19 is sandwiched by the first insulation films 18, the semiconductor device 1c can be carried out with a plurality of second insulation films 19 formed on each side surface of the field plate electrode 16.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductivity-type drain layer;
a first conductivity-type drift layer formed on the drain layer;
a second conductivity-type base layer formed on the drift layer;
a first conductivity-type source layer which is selectively formed on a surface of the base layer;
a trench region formed through a surface of the source layer such that the trench region reaches the drift layer from the surface of the source layer;
a gate electrode formed adjacent to the base layer and inside the trench region, and surrounded by a first insulation film;
a field plate electrode formed in the trench region below the gate electrode and surrounded by a second insulation film having a higher dielectric constant than the first insulation film;
a drain electrode which is electrically connected to the drain layer; and
a source electrode electrically connected to the source layer.

2. The semiconductor device according to claim 1, wherein the first insulating film is formed below the field plate electrode.

3. The semiconductor device according to claim 2, wherein the second insulation film is formed on a side surface of the field plate electrode but not below the field plate electrode.

4. The semiconductor device according to claim 1, wherein the second insulation film is surrounded by the first insulation film.

5. The semiconductor device according to claim 4, wherein the first insulation film is further formed between the side surface of the field plate electrode and the second insulation film.

6. The semiconductor device according to claim 1, wherein a thickness of the second insulation film that surrounds the field plate electrode is larger than a thickness of the first insulation film between the gate electrode and the source electrode.

7. The semiconductor device according to claim 1, wherein the second insulation film comprises silicon nitride.

8. The semiconductor device according to claim 7, wherein the first insulation film comprises silicon oxide.

9. The semiconductor device according to claim 1, wherein a thickness of the second insulation film is larger than a thickness of the first insulation film.

10. A method for manufacturing a semiconductor device, comprising:
forming a first conductivity-type drain layer:
forming a first conductivity-type drift layer on the drain layer;
forming a plurality of trenches in the drift layer;
forming a first insulation film in a bottom portion of the trenches;
forming a field plate electrode in each of the trenches above the first insulation film such that a space is maintained between the field plate electrode and sidewalls of the trench;
filling the space within each trench with a second insulation film;
forming a third insulation film on sidewalls of the trenches and above the second insulation film and each field plate electrode; and
forming a gate electrode to be surrounded by the third insulation film in each of the trenches,
wherein the second insulation film has a higher dielectric constant than the third insulation film.

11. The method according to claim 10, wherein the second insulation film has a higher dielectric constant than the first insulation film.

12. The method according to claim 11, wherein the first insulating film and the third insulation film are made of the same material.

13. The method according to claim 12, wherein the first and third insulation films comprise silicon oxide, and the second insulation film comprises silicon nitride.

14. The method according to claim 10, wherein a thickness of the second insulation film is larger than a thickness of the third insulation film.

15. A method for manufacturing a semiconductor device, comprising:
forming a first conductivity-type drain layer:
forming a first conductivity-type drift layer on the drain layer;
forming a plurality of trenches in the drift layer;
forming a first insulation film in a bottom portion of the trenches;
forming a field plate electrode in each of the trenches above the first insulation film;
forming a second insulation film on sidewalls of the trenches and on side surfaces of each field plate electrode such that a space is maintained between the second insulation film on the sidewalls of the trenches and the second insulation film on the side surfaces of each field plate electrode;
filling the space between the second insulation film on the sidewalls of the trenches and the second insulation film on the side surfaces of each field plate electrode with a third insulation film; and
forming a gate electrode in each of the trenches above the respective field plate electrode,
wherein the third insulation film has a higher dielectric constant than the first and second insulation films.

16. The method according to claim 15, wherein the first and second insulation films are made of the same material.

17. The method according to claim 16, wherein the first and second insulation films comprise silicon oxide, and the third insulation film comprises silicon nitride.

18. The method according to claim 15, further comprising:
forming a fourth insulation film on sidewalls of the trenches and above the second and third insulation films and each field plate electrode,
wherein each gate electrode is surrounded by the fourth insulation film in each of the trenches.

19. The method according to 18, wherein the third insulation film has a higher dielectric constant than the fourth insulation film.

20. The method according to claim 15, wherein the first, second, and fourth insulation films are made of the same material.
